(19) United States
(12) Patent Application Publication
(10) Pub. No.: US 2012/0073629 A1
(43) Pub. Date: Mar. 29, 2012

(54) SOLAR CELL MODULE AND METHOD OF MANUFACTURING THE SAME

(75) Inventors: Woei-yuan Wu, Taoyuan (TW); Chun-yi Lee, Taoyuan (TW)

(73) Assignee: Perfect Source Technology Corp., Taoyuan (TW)

(21) Appl. No.: 12/890,756

(22) Filed: Sep. 27, 2010

(51) Int. Cl. H01L 31/048; H01L 31/18

(52) U.S. Cl. 136/251; 438/66; 257/E31.117

(57) ABSTRACT

An improved solar cell module and a method of manufacturing the same are disclosed in the invention. The solar cell modules includes: a solar cell matrix, having a number of conductive wires, for transforming solar energy into electric energy to be outputted; a front sheet, formed on one side of the solar cell matrix, for passing solar light; a back sheet, formed on the other side of the solar cell matrix, for passing solar light; and an isolating cover, covering the solar cell matrix, for protecting the solar cell matrix from stress, humidity and heat. A number of holes are formed through the back sheet and the isolating cover, the conductive wires are soldered with insulated cables passing through the holes, and an adhesive is used to seal the hole and fix the cables.

### FIELD OF THE INVENTION

The present invention relates generally to an improved solar cell module. More specifically, the present invention relates to an improved solar cell module having holes for connecting conductive wires with insulated cables such that tapes are not required during manufacture.

### BACKGROUND OF THE INVENTION

Among the recent world spread consciousness of ecological and environmental protection issues, the deepest concern is directed to the warming of the earth by CO₂ production, and the development and stable supply of clean energy are urgently desired objectives. The solar cell is one of the most promising clean energy sources because of its safety and ease of handling. Solar cells have been prepared in various forms such as (a) monocrystalline silicon solar cells; (b) polycrystalline silicon solar cells; (c) amorphous silicon solar cells; (d) copper-indium selenide solar cells; and (e) compound semiconductor solar cells. Among these types of cells, the thin film crystalline silicon solar cells, compound semiconductor solar cells, and amorphous silicon solar cells are recent targets of active development as they are relatively inexpensive and can be formed into a large area.

Traditional manufacturing processes of solar cell modules are: (a) making solar cell string; (b) arranging the solar cell strings to be a solar cell matrix; (3) processing lamination process with a piece of glass, ethylene-vinyl acetate (EVA), the solar cell matrix and back sheet in series; (4) wiring the laminated solar cell matrix with a junction box; and (5) assembling aluminum frame. However, there are some problems that need to be improved.

When the module is in the lamination process, conductive wires are commonly connected with a terminal box by passing through the EVA and back sheet. Some shortcomings follow. First, since the conductive wires go through the EVA and the back sheet, the EVA and back sheet need to be punched or cut before lamination process. In order to avoid the solar cell strings from shifting during ribbon through the holes, tapes are required to fix them together. However, the tapes may cause stability problem for the solar cell module in long term.

Secondly, power leakage and even short circuit still exist. When the solar module is under the manufacturing processes, non-insulated cables are commonly used to connect the conductive wires and the terminal box. If the conductive wires are too close one another, the solar cell module will easily have power leakage or short circuit between the ribbons when generating electric power. Furthermore, it causes danger to human bodies and fire.

In order to solve these two problems mentioned above, U.S. Pat. No. 6,340,403 provides an improved structure. Please refer to FIG. 1. A solar cell module laminate structure indicated generally at 10, consists of a number of individual solar cells 11, only two shown, which are electrically interconnected, as known in the art such as by soldering and encapsulated between two fluoropolymer/adhesive layers generally indicated at 13 and 14, each of the encapsulation layers being composed of a layer of adhesive 15 and a layer of fluoropolymer 16. A quantity, block, or layer 12 of fluoropolymer material is positioned intermediate the solar cells 11.

As pointed at above, in '403 the solar cells 11 are silicon solar cells having a thickness of 100 μm (4 mil) and spaced 1250 μm (50 mil) apart, the adhesive layers 15 are composed of silicone adhesive having a thickness of 50 μm (2 mil), and the fluoropolymer layers 12 and 16 are composed of 50 μm (2 mil) thick E-CTFE. The silicone adhesive, for example, may be of the type manufactured by Dielectric Polymers, Inc. under the trademark TRANS-SIL, for example, but is a commercially available and widely used product. The thickness of the solar cells 11 may vary within the module 10 and be up to 25 mils thick (625 μm). The thickness of the adhesive layers 15 may vary from 10-50 μm (0.4-2 mil). The thickness of the fluoropolymer layers 16 may vary from 5-260 μm (0.2-5 mil). The thickness of either or both of the adhesive layers and the fluoropolymer layers 16 will depend on the specific materials involved, construction of the solar cells, and the applications in which the solar modular laminate structure is to be utilized.

'403 provides a hermetically sealed solar cell module laminate structure that is flexible and very durable and has the ability to withstand the hostile conditions imposed by environments such as those in high altitudes. This invention provides a lamination process that can be used, for example, to encapsulate high power to weight ratio solar cell arrays for protecting such from adverse environmental conditions, and which enables use of such solar cell arrays in solar powered craft, such as to solar airplane Pathfinder and various types of spacecraft. At high altitudes there is little to no attenuation of the ultra-violet (UV) part of the solar spectrum in addition to extreme thermal variations, and the solar cell array laminate must be able to withstand these conditions to protect the solar cells.

However, only new materials used for lamination process can not permanently solve the problems mentioned above. The most important reason is no more care of wired cables in the solar cell structure. Although solar cells can be well protected, protection of wired cables is not considered. The cables will have power leakage or even cause circuit shortage after long time use. Therefore, a method for overcoming the above problems in manufacturing a solar cell module is still desired.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims.

In accordance with an aspect of the present invention, an improved solar cell module includes: a solar cell matrix, having a number of conductive wires, for transforming solar energy into electric energy to be outputted; a front sheet, formed on one side of the solar cell matrix, for passing solar light; a back sheet, formed on the other side of the solar cell matrix, for passing solar light; and an isolating cover, covering the solar cell matrix, for protecting the solar cell matrix from stress, humidity and heat. A number of holes are formed through the back sheet and the isolating cover, the conductive wires are soldered with insulated cables passing through the holes, and an adhesive is used to seal the hole and fix the cables.

Preferably, the isolating cover is made of ethylene-vinyl acetate (EVA), polytetrafluoroethylene (PTFE) or casting resin.

Preferably, the front sheet is made of polymethyl methacrylate (PMMA), polytetrafluoroethylene (PTFE), polyethylene terephthalate (PET), a glass or a plastic.

Preferably, the back sheet is made of polymethyl methacrylate (PMMA), polytetrafluoroethylene (PTFE), polyethylene terephthalate (PET), a glass or a plastic.

Preferably, the adhesive comprises silicone.

In accordance with an aspect of the present invention, a method for manufacturing an improved solar cell module includes the steps of: a) providing a solar cell matrix, having a number of conductive wires, for transforming solar energy into electric energy to be outputted; b) forming a front sheet and a back sheet on both sides of the solar cell matrix for passing solar light; c) sandwiching an isolating cover covering the solar cell matrix for protecting the solar cell matrix from stress, humidity and heat; d) pressing side by side the front sheet, the solar cell matrix, the isolating cover, and the back sheet in sequence; e) drilling holes through the back sheet and the isolating cover; f) soldering the conductive wires in the solar cell matrix with insulated cables passing through the holes; and g) sealing the holes and fixing the cables with an adhesive.

Preferably, the isolating cover is made of ethylene-vinyl acetate (EVA), polytetrafluoroethylene (PTFE) or casting resin.

Preferably, the front sheet is made of polymethyl methacrylate (PMMA), polytetrafluoroethylene (PTFE), polyethylene terephthalate (PET), a glass or a plastic.

Preferably, the back sheet is made of polymethyl methacrylate (PMMA), polytetrafluoroethylene (PTFE), polyethylene terephthalate (PET), a glass or a plastic.

Preferably, the pressing step is carried out in a vacuum chamber.

Preferably, the adhesive comprises silicone.

### BRIEF DESCRIPTION OF THE DRAWINGS

FIG. 1 shows a prior art of an improved solar cell module.

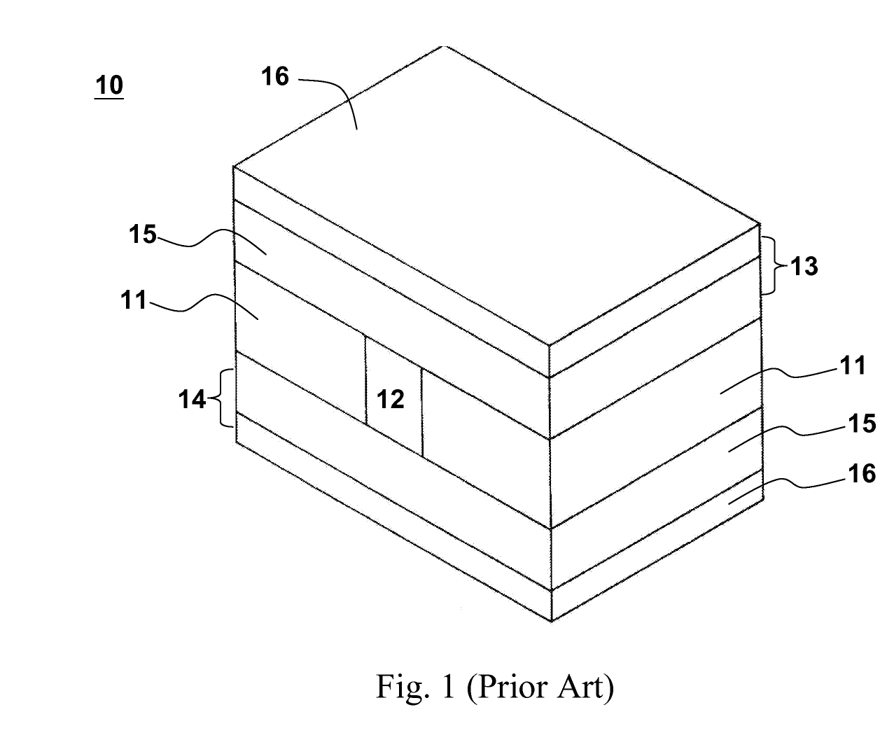

FIG. 2 is a flow chart for an embodiment of the present invention.

FIG. 3 illustrates a structure of a solar cell module in the present invention during lamination.

FIG. 4 is an enlarged view of a solar cell matrix in the present invention.

FIG. 5 is an enlarged view of holes in an EVA layer in the present invention.

FIG. 6 is an enlarged view of holes in a back sheet in the present invention.

FIG. 7 shows an insulated cable used in the embodiment of the present invention.

FIG. 8 shows the sealed holes on the back sheet in the embodiment of the present invention.

### DETAILED DESCRIPTION OF THE PREFERRED EMBODIMENT

For better understanding of the present invention, an embodiment is used for better description below.

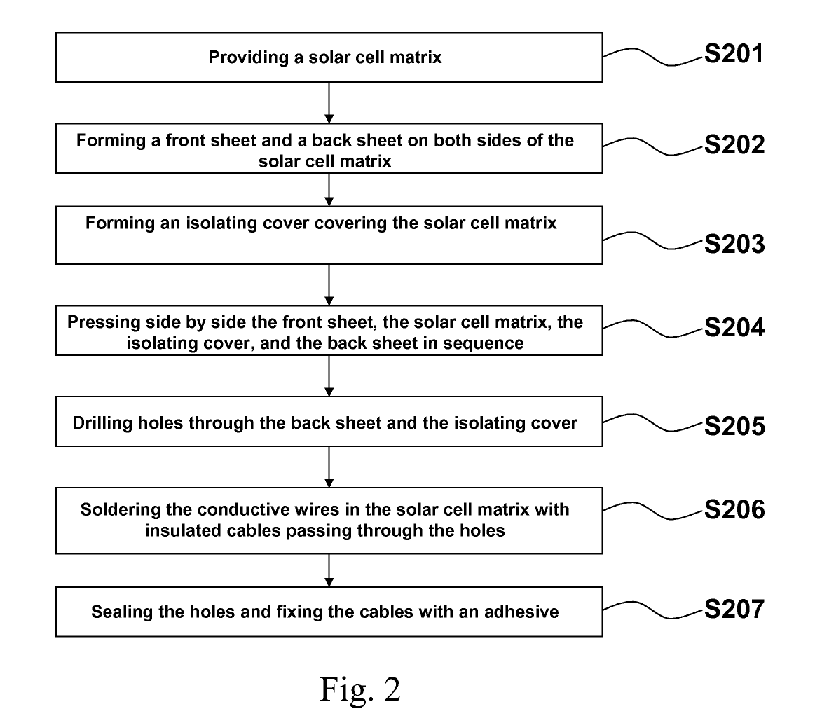

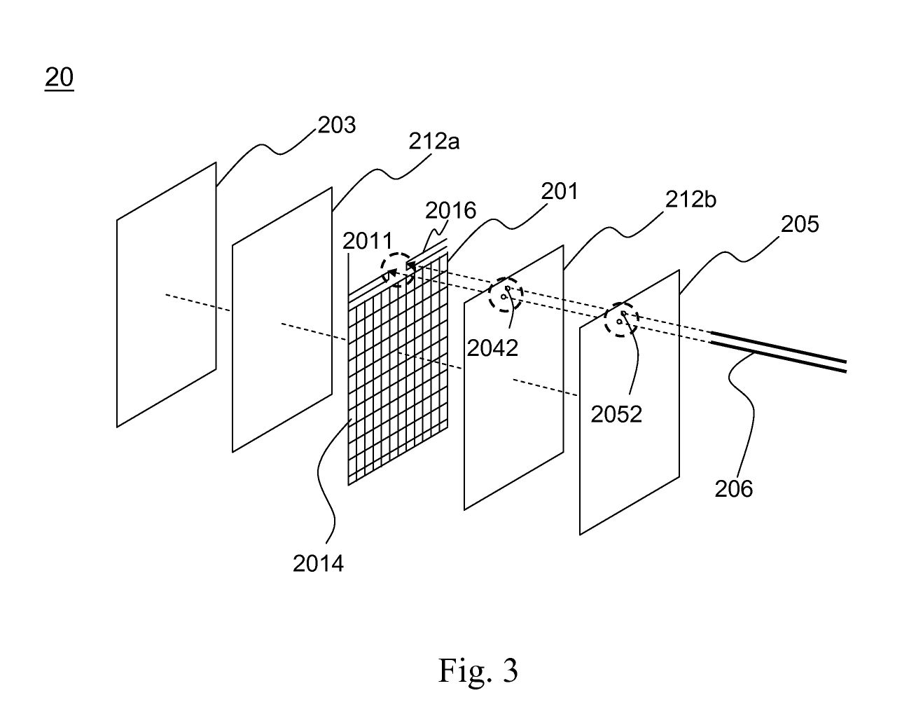

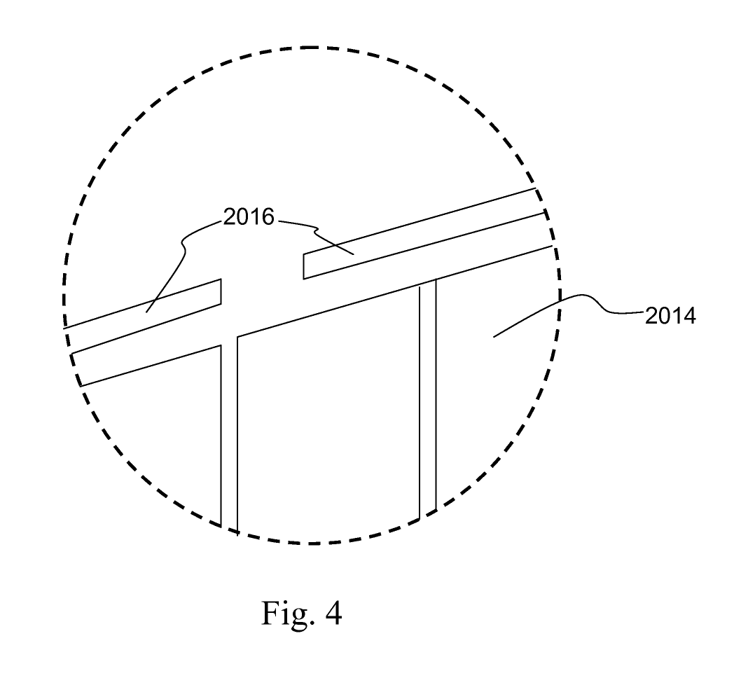

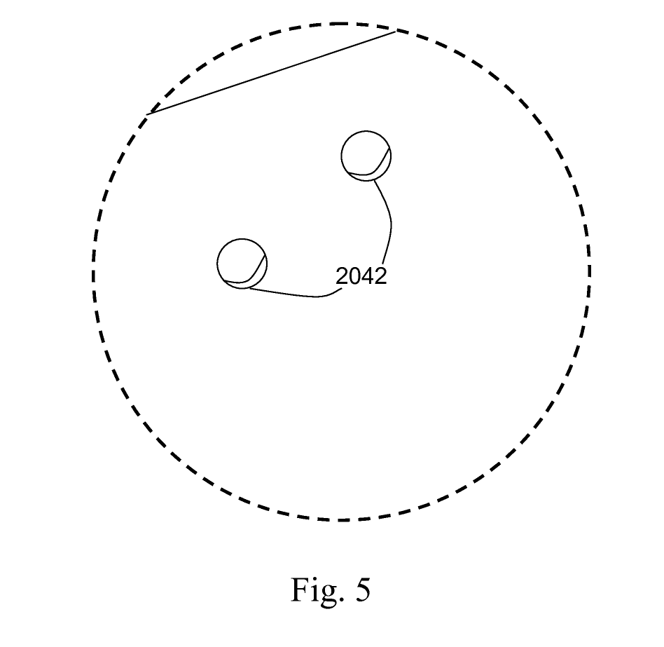

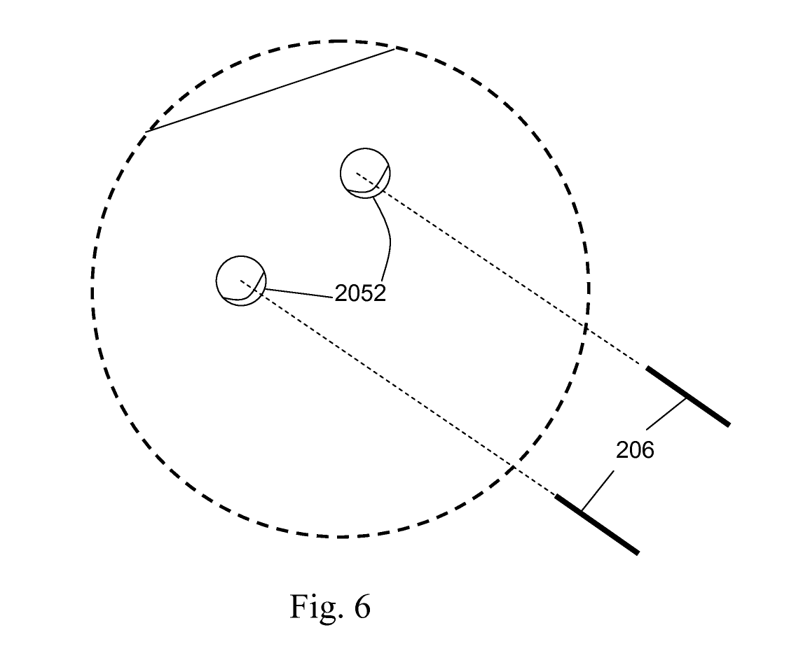

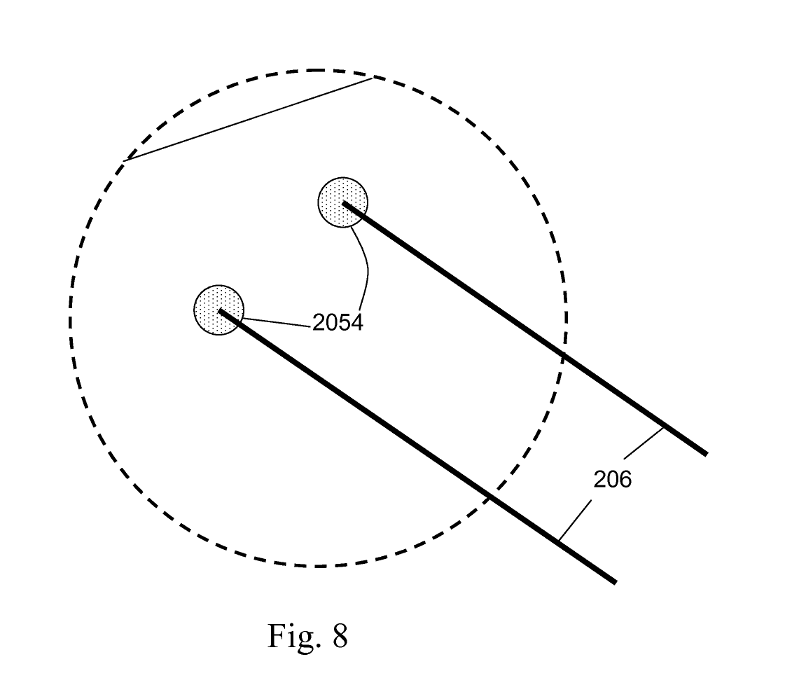

FIG. 2 to FIG. 8 show the embodiment of the present invention. FIG. 2 is a flow chart for the method of the present invention. FIG. 3 to FIG. 8 illustrate the details of the present invention. Please refer to FIG. 2, FIG. 3, FIG. 4 and FIG. 8 at the same time. FIG. 3 is an explosive view of the present invention. FIG. 4 and FIG. 8 show some enlarged details in FIG. 4. The steps of method for manufacturing an improved solar cell module 20 in FIG. 2 are stated below.

A solar cell matrix 201 is provided which has a number of conductive wires 2016 for transforming solar energy into electric energy to be outputted (S201). The solar cell matrix 201 is composed of many solar cells 2014. A jig (not shown) is used to arrange certain solar cells 2014 as a solar cell string 2011. Then several solar cell strings 2011 form the solar cell matrix 201.

A front sheet 203 and a back sheet 205 are formed on both sides of the solar cell matrix 201 for passing solar light (S202). In this embodiment, the solar cell matrix 201 is covered by isolating covers 212a and 212b for protecting the solar cell matrix 201 from stress, humidity and heat (S203). Alternatively, one isolating cover can be used.

The front sheet 203, the isolating covers 212a and 212b, and the back sheet 205 are pressed side by side in sequence (S204). The process is called lamination. It is to form the basic structure of the solar cell module 20. Next, holes 2052 and 2042 are drilled through the back sheet 205 and the isolating cover 212b (S205).

The conductive wires 2016 in the solar cell matrix 201 are soldered with insulated cables 206 passing through the holes 2052 and 2042 (S206).

The holes 2052 and 2042 are sealed and the cables 206 are fixed with an adhesive 2054. The adhesive 2054 used in the present invention is silicone.

In the embodiment, the isolating covers 212a and 212b are both formed by ethylene-vinyl acetate (EVA). In practice, they can be made of polytetrafluoroethylene (PTFE) or casting resin. Glass is used in the front sheet 203 in the embodiment. However, it is not limited to glass. It can be made of polymethyl methacrylate (PMMA), polytetrafluoroethylene (PTFE), polyethylene terephthalate (PET) or plastic as long as it is transparent to light beams with lower absorptivity. The back sheet 205 is a plastic sheet. For some solar cell modules, solar energy can be received on both sides, so the back sheet can be designed as transparent. Therefore, glass, PMMA, PTFE, or PET can be used. It should be emphasized that the lamination process is carried out in a vacuum chamber. By controlling pressure and temperature, EVA will melt and form isolating covers 212a and 212b to protect the solar cell matrix 201 from stress, humidity and heat.

In order to illustrate details and functions of the improved solar cell module 20, please refer to FIG. 3 to FIG. 8. As shown in FIG. 3, the solar cell matrix 201 is composed of solar cells 2014. It can transform solar energy into electric energy. The isolating covers 212a and 212b are able to protect the solar cell matrix 201 from stress, humidity and heat. The front sheet 203, formed on the isolating cover 212a, is used to pass solar light beams. The back sheet 205, formed on the isolating cover 212b is used to pass solar light beams.

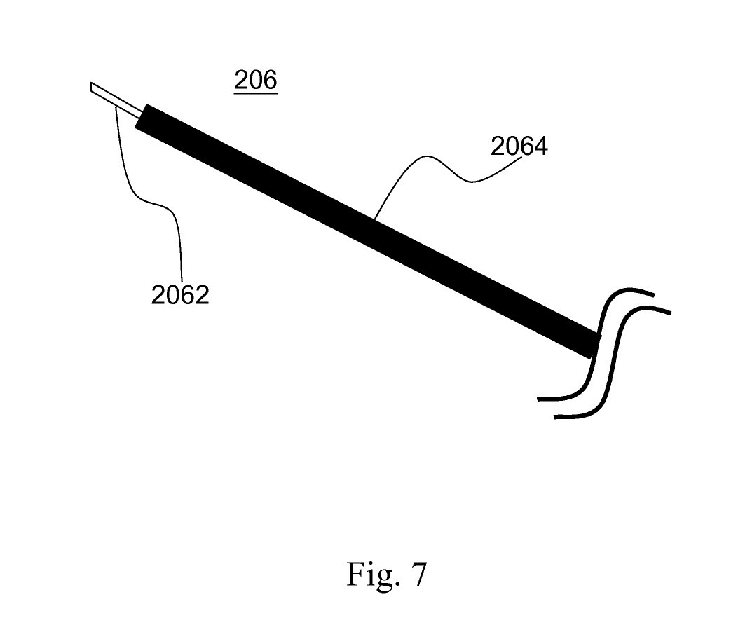

A number of holes 2052 are formed on the back sheet 205 and a number of holes 2042 are formed on the isolating cover 212b. The conductive wires 2016 are soldered with insulated cables 206 passing through the holes 2052 and 2042. Please refer to FIG. 7. The cable 206 has a core 2062 enclosed by an insulated material 2064, such as polyvinylchloride (PVC) or polybutylene terephthalate (PBT). Adhesive (silicone) 2054 is used to seal the holes 2052 and 2042 and fix the cables (S207).

In comparison with the conventional methods for manufacturing solar cell modules, the present invention uses jigs to fix solar cell strings so that no shifting of solar strings will occur. Of course, tapes for fixing can be avoided. Therefore, long term stability of the solar cell module can be obtained. Meanwhile, insulated cables are used to pass through the EVA and the back sheet so that it is not needed to drill holes on the EVA and back sheet before lamination processes. With help of silicone, there is a protective insulation layer formed to keep the solar cell module from power leakage and short circuit between conductive wires. The two problems mentioned in the background of the invention are overcomed.

While the invention has been described in terms of what is presently considered to be the most practical and preferred embodiment, it is understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures

What is claimed is:

1. An improved solar cell module, comprising:
a solar cell matrix, having a plurality of conductive wires, for transforming solar energy into electric energy to be outputted;
a front sheet, formed on one side of the solar cell matrix, for passing solar light;
a back sheet, formed on the other side of the solar cell matrix, for passing solar light; and
an isolating cover, covering the solar cell matrix, for protecting the solar cell matrix from stress, humidity and heat;
wherein a plurality of holes are formed through the back sheet and the isolating cover, the conductive wires are soldered with insulated cables passing through the holes, and an adhesive is used to seal the hole and fix the cables.

2. The improved solar cell module according to claim 1, wherein the isolating cover is made of ethylene-vinyl acetate (EVA), polytetrafluoroethylene (PTFE) or casting resin.

3. The improved solar cell module according to claim 1, wherein the front sheet is made of polymethyl methacrylate (PMMA), polytetrafluoroethylene (PTFE), polyethylene terephthalate (PET), a glass or a plastic.

4. The improved solar cell module according to claim 1, wherein the back sheet is made of polymethyl methacrylate (PMMA), polytetrafluoroethylene (PTFE), polyethylene terephthalate (PET), a glass or a plastic.

5. The improved solar cell module according to claim 1, wherein the adhesive comprises silicone.

6. A method for manufacturing an improved solar cell module, comprising the steps of:
a) providing a solar cell matrix, having a plurality of conductive wires, for transforming solar energy into electric energy to be outputted;
b) forming a front sheet and a back sheet on both sides of the solar cell matrix for passing solar light;
c) forming an isolating cover, covering the solar cell matrix, for protecting the solar cell matrix from stress, humidity and heat;
d) pressing side by side the front sheet, the isolating cover, and the back sheet in sequence;
e) drilling holes through the back sheet and the isolating cover;
f) soldering the conductive wires in the solar cell matrix with insulated cables passing through the holes; and
g) sealing the holes and fixing the cables with an adhesive.

7. The method according to claim 6, wherein the isolating cover is made of ethylene-vinyl acetate (EVA), polytetrafluoroethylene (PTFE) or casting resin.

8. The method according to claim 6, wherein the front sheet is made of polymethyl methacrylate (PMMA), polytetrafluoroethylene (PTFE), polyethylene terephthalate (PET), a glass or a plastic.

9. The method according to claim 6, wherein the back sheet is made of polymethyl methacrylate (PMMA), polytetrafluoroethylene (PTFE), polyethylene terephthalate (PET), a glass or a plastic.

10. The method according to claim 6, wherein the pressing step is carried out in a vacuum chamber.

11. The method according to claim 6, wherein the adhesive comprises silicone.
